(19) United States
(12) Patent Application Publication
(10) Pub. No.: US 2018/0130761 A1
(43) Pub. Date: May 10, 2018

(54) SEMICONDUCTOR PACKAGE, MANUFACTURING METHOD THEREOF, AND ELECTRONIC ELEMENT MODULE USING THE SAME

(71) Applicant: SAMSUNG ELECTRO-MECHANICS CO., LTD., Suwon-si (KR)

(72) Inventors: Tae Hyun KIM, Suwon-si (KR); Chang Soo KANG, Suwon-si (KR)

(73) Assignee: SAMSUNG ELECTRO-MECHANICS CO., LTD., Suwon-si (KR)

(21) Appl. No.: 15/640,732

(22) Filed: Jul. 3, 2017

(30) Foreign Application Priority Data
Nov. 9, 2016 (KR) 10-2016-0149122
Feb. 28, 2017 (KR) 10-2017-0026215

(51) Int. Cl. H01L 23/00; H01L 23/538; H03F 3/21; H01L 21/48; H01L 21/56; H01L 23/367

(52) U.S. Cl. CPC H01L 24/20; H01L 23/5386; H01L 24/05; H03F 3/21; H01L 23/5389; H01L 25/0652; H01L 21/486; H01L 21/56; H01L 24/19; H01L 23/367; H01L 23/5384

(57) ABSTRACT

A semiconductor package includes a board part including a core layer having an element accommodating region disposed therein, and build-up layers disposed on top and bottom surfaces of the core layer; an electronic element disposed in the element accommodating region; and block conductors disposed on the build-up layers and electrically connected to terminals of the electronic element.

### CROSS-REFERENCE TO RELATED APPLICATION(S)

This application claims the benefit under 35 USC 119(a) of Korean Patent Application Nos. 10-2016-0149122 filed on Nov. 9, 2016, and 10-2017-0026215 filed on Feb. 28, 2017, in the Korean Intellectual Property Office, the entire disclosure of both which are incorporated herein by reference for all purposes.

### BACKGROUND

### 1. Field

The following description relates to a semiconductor package, a manufacturing method thereof, and an electronic element module using the same.

### 2. Description of Related Art

One of the recent main trends of the development of technology related to semiconductor chips is to reduce the size of the components. In order to decrease the size of semiconductor chips, in the package field, it has been necessary to implement a plurality of fins having a small size.

One of the package technologies suggested to satisfy the above-mentioned requirement is a fan-out semiconductor package. The fan-out semiconductor package rewires a connection terminal to the outside of the region on which the semiconductor chip is disposed, to enable a plurality of fins to be implemented, while having a small size.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a semiconductor package includes a board part including a core layer having an element accommodating region disposed therein, and build-up layers disposed on top and bottom surfaces of the core layer. The semiconductor package further includes an electronic element disposed in the element accommodating region, and block conductors disposed on the build-up layers and electrically connected to terminals of the electronic element.

The block conductors may be directly formed on the terminals of the electronic element through a plating method.

Rewiring layers may be disposed on the terminals of the electronic element, and the block conductors may be disposed on wiring layers that are disposed on the rewiring layers.

The rewiring layers may be disposed within the element accommodating region.

The general aspect of the semiconductor package may further include insulating protective layers disposed on the build-up layers, and the insulating layers may include one or more openings that partially expose the block conductors.

The electronic element may be a power amplifier, and the terminals may include a plurality of power terminals and a plurality of ground terminals.

The block conductors may include a first block conductor connected to the plurality of power terminals, and a second block conductor connected to the plurality of ground terminals.

The block conductors and the build-up layers may have substantially the same thickness.

The block conductors may be disposed on an active surface of the electronic element.

The terminals of the electronic element may be formed as pads having a size corresponding to an area of the block conductors, and the block conductors may be formed by growing a conductive material from the terminals, by a plating method.

In another general aspect, a method of manufacturing a semiconductor package involves disposing an electronic element in an element accommodating region of a core layer; and forming build-up layers by forming an insulating layer and a wiring layer on top and bottom surfaces of the core layer, in which the forming of the build-up layers involves forming one or more block conductors that is electrically connected to terminals of the electronic element in the insulating layer.

The disposing of the electronic element in the element accommodating region may involve forming a through hole in the core layer to obtain the element accommodating region.

The forming of the block conductors may involve: forming the insulating layer on the core layer; forming cavities in the insulating layer; and forming the block conductors by filling a conductive material into the cavities.

The forming of the cavities may involve an exposure operation and an etching operation.

The general aspect of the method may further involve, after the forming of the build-up layers, forming an insulating protective layer on the build-up layers.

In another general aspect, an electronic element module includes a semiconductor package including an electronic element disposed within a core layer, a build-up layer laminated on the core layer, and one or more block conductor disposed within the build-up layer to discharge heat of the electronic element; and at least one electronic component mounted on the semiconductor package.

The general aspect of the electronic element module may further include a metal layer disposed along an interface between the semiconductor package and the electronic component to block electromagnetic wave.

In another general aspect, a semiconductor package includes an electronic element disposed within a core layer, terminals of the electronic element being exposed through an opening of the core layer; a build-up layer covering the opening of the core layer; and a block conductor disposed within the build-up layer and is electrically connected to the terminals.

The build-up layer may contact the electronic element.

In the general aspect of the semiconductor package, one or more block conductors may be disposed within the build-up layer, and the one or more block conductors and the build-up layer may substantially seal the opening through which the terminals of the electronic element are exposed from the core layer.

Other features and aspects will be apparent from the following detailed description, the drawings, and the claims.

### BRIEF DESCRIPTION OF DRAWINGS

FIG. 1 is a cross-sectional view schematically illustrating an example of a semiconductor package.

FIG. 2 is an enlarged cross-sectional view of part A of the example of a semiconductor package illustrated in FIG. 1.

FIGS. 3A through 3E are views illustrating additional examples of block conductors.

FIGS. 4A through 6C are views illustrating an example of a method of manufacturing a semiconductor package as illustrated in FIG. 1.

FIG. 7 is a cross-sectional view schematically illustrating another example of a semiconductor package.

FIG. 8 is a cross-sectional view schematically illustrating an example of an electronic element module.

FIG. 9 is a cross-sectional view schematically illustrating another example of an electronic element module.

FIG. 10 is a cross-sectional view schematically illustrating another example of an electronic element module according to the present description.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Hereinafter, various examples of the present disclosure will be described in detail with reference to the accompanying drawings.

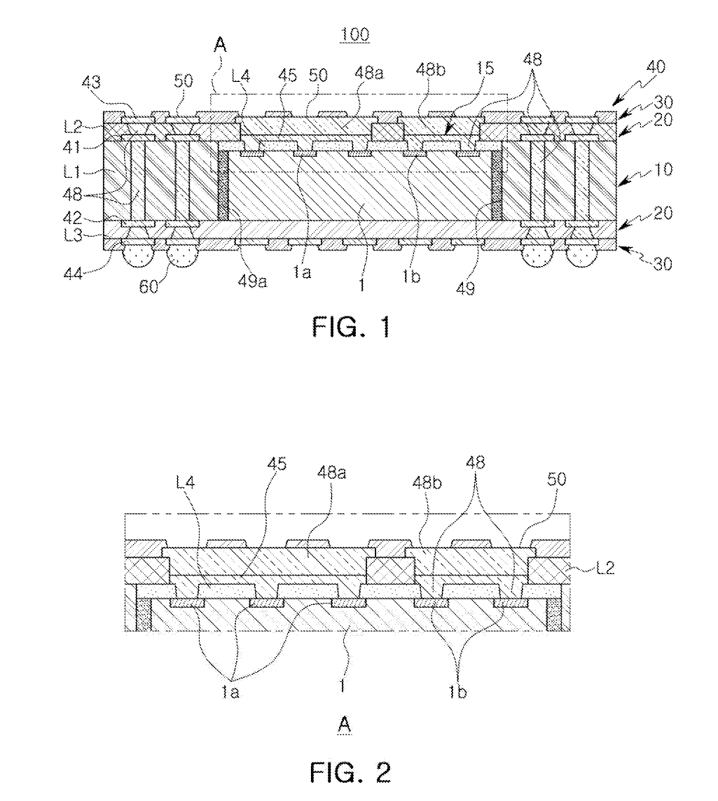

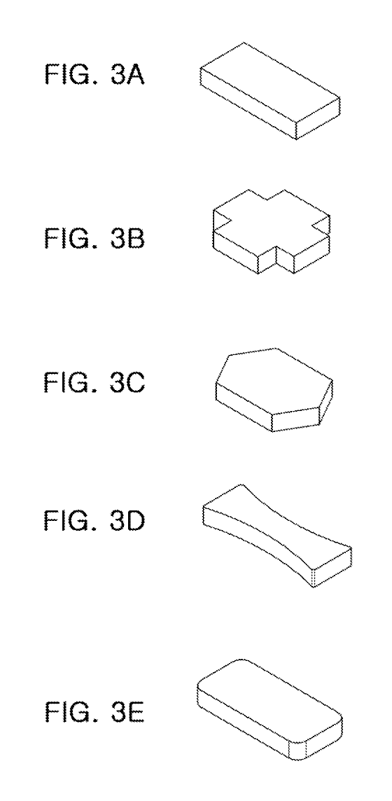

FIG. 1 is a cross-sectional view schematically illustrating an embodiment of a semiconductor package, and FIG. 2 is an enlarged cross-sectional view of part A of the embodiment of the semiconductor package illustrated in FIG. 1.

Referring to FIGS. 1 and 2, a semiconductor package 100 includes a board part 40 and at least one electronic element 1 embedded within the board part 40.

The board part 40 includes a plurality of insulating layers L1 to L4 and wiring layers 41 to 45, which are repeatedly laminated, and includes an element accommodating region 49 provided within one of the insulating layers L1 to L4.

The board part 40 may be divided into a core layer 10, one or more build-up layers 20 laminated on outer surfaces of the core layer 10, one or more insulating protective layers 30 laminated on outer surfaces of the build-up layers 20, and a rewiring layer 15 disposed within the core layer 10.

The insulating layers L1 to L4 of the board part 40 may be formed of a resin material having an insulating property. As a material for forming the insulating layers L1 to L4, a thermosetting resin such as an epoxy resin, a thermoplastic resin such as polyimide, a resin having a reinforcement material such as glass fiber or inorganic filler impregnated therein, such as a prepreg, may be used. However, the material for forming the insulating layers is not limited thereto.

The insulating layer L1 of the core layer 10, the insulating layers L2 and L3 of the build-up layers 20, and the insulating layer L4 of the rewiring layer 15 may be formed of different materials from each other, or may be partly formed of the same material. For example, the insulating layer L1 of the core layer 10 may be formed of a polymer material, and the insulating layers L2, L3, and L4 of the rewiring layer 15 may be formed of an epoxy material, or vice versa. Various additional modifications are possible based on the application of the semiconductor package 100. In yet another example, all of the insulating layers L1 to L4 may be formed of the same material.

The wiring layers 41 to 45 may be disposed on one surface or on both top and bottom surfaces of the insulating layers L1 to L4, respectively.

In the example illustrated in FIG. 1, the wiring layers 43 and 44 are disposed as the outermost layers among the wiring layers 41 to 45 that make up the board part 40, and the wiring layers 43 and 44 are partially exposed to the outside, to serve as connection pads 50.

Connection conductors 48 are disposed throughout the insulating layers L1 to L4, respectively, so as to penetrate through the insulating layers L1 to L4. The interlayer connection conductors 48 may electrically connect to the connection pads 50 or may connect the wiring layers 41 to 45 with each other.

The wiring layers 41 to 45 and the interlayer connection conductors 48 may be formed by a photolithography method. For example, the wiring layers 41 to 45 may be formed by patterning a metal layer, such as a copper (Cu) foil. In addition, the interlayer connection conductors 48 may be obtained by forming via holes in the insulating layers L1 to L3 and then filling a conductive material into the via holes. However, the configuration of the present disclosure is not limited thereto.

In FIG. 1, the core layer 10 is disposed in the center of the board part 40 and formed as a single layer. However, the configuration of the core layer 10 is not limited thereto. In another example, the core layer 10 may also be formed as, for instance, a multilayer substrate.

In this example, an element accommodating region 49 is formed within the board part 40. At least one electronic element 1 is embedded within the element accommodating region 49.

The element accommodating region 49 is formed within the core layer 10 as to be embedded in the core layer 10. In this example, portions of the element accommodating region 49 extend to the build-up layers 20 so as to be enclosed by the build-up layers 20. However, the configuration of the element accommodating region is not limited thereto.

An insulating member 49a is disposed within the element accommodating region 49. In this example, the insulating member 49a is formed within the element accommodating region 49 in order to fill a space or gap between the electronic element 1 and the core layer 10.

The insulating member 49a may have an insulating property, and may be formed of a material that may easily fill the space or gap between the element accommodating region 49 and the electronic element 1 placed therein. For example, the insulating member 49a may be formed by filling the space or gap between the element accommodating region 49 and the electronic element 1 with a B-stage resin or polymer and then curing the B-stage resin or polymer. However, the method of forming the insulating material 49a is not limited thereto.

The electronic element 1 that is embedded within the element accommodating region 49 may be a heating element that generates a large amount of heat during an operation thereof. For example, the electronic element 1 may be a power amplifier. However, the configuration of the semiconductor package 100 is not limited thereto. For example, the electronic element 1 may be selected from a variety of elements such as a filter, an integrated circuit (IC), a switching element, and the like. A variety of elements may be used to implement the electronic element 1, and the element may generate a large amount of heat and be embedded within the board part.

In this example, the electronic element 1 is accommodated in the element accommodating region 49 as a bare die or a bare chip that is cut from a wafer. By accommodating the electronic element 1 as a bare die or a bare chip, the overall size of the semiconductor package 100 may be significantly reduced.

Referring to FIG. 1, the electronic element 1 includes an active surface and an inactive surface, and the inactive surface is provided on a side of the electronic element 1 opposite from the active surface. Terminals are formed on the active surface, and terminals are not provided on the inactive surface. In addition, the terminals of the electronic element 1 includes power terminals 1a and ground terminals 1b. However, the arrangement of the active and inactive surfaces is not limited thereto.

In this example, the rewiring layer 15 is disposed within the element accommodating region 49 of the core layer 10, and is formed on the active surface of the electronic element 1. The rewiring layer 15 electrically connects the terminals 1a and 1 b of the electronic element 1 with block conductors 48a and 48b, to be described below.

To this end, in this example, the rewiring layer 15 includes the insulating layer L4, the plurality of interlayer connection conductors 48, disposed within the insulating layer L4, and the wiring layer 45, disposed on the insulating layer L4.

As described above, the insulating layer L4 of the rewiring layer 15 may be selectively formed of any one of a thermosetting resin such as an epoxy resin, a thermoplastic resin such as polyimide, and a resin impregnated with a reinforcement material such as glass fiber or inorganic filler. However, the material and the arrangement of layers are not limited thereto.

The wiring layer 45 disposed within the rewiring layer 15 may electrically connect the power terminals 1a disposed on the active surface of the electronic element 1 with each other. In addition, the wring layer 45 may electrically connect the ground terminals with each other.

Because the rewiring layer 15 is disposed within the element accommodating region 49 of the core layer 10, in this example, the wiring layer 45 of the rewiring layer 15 is disposed on the same plane as the wiring layer 41 of the core layer 45. However, the arrangement of wiring layer 45 and the rewiring layer 15 is not limited thereto.

In the illustrated example, the build-up layers 20 are disposed on both top and bottom surfaces of the core layer 10. The build-up layers 20 are formed on the core layer 10 by a build-up method.

The insulating layers L2 and L3 configuring the build-up layers 20 may be formed of the same material, or be formed of two different materials, as needed. In addition, the build-up layers 20 may be formed of a material capable of forming a cavity 26 as illustrated in FIG. 5C, such that the block conductors 48a and 48b are disposed therein through an exposure and etching operation.

The insulating protective layer 30 may be formed of solder resist. However, the material for forming the insulating protective layer 30 is not limited thereto.

In this example, two insulating protective layers 30 are disposed outside of the corresponding build-up layers 20. Therefore, the insulating protective layers 30 form the outermost surfaces of the board part 40. In addition, the insulating protective layers 30 include a plurality of openings that expose the connection pads 50 to the outside. The block conductors 48a and 48b are exposed to the outside of the board part 40 through the openings. However, the arrangement of the insulating protective layers 30 and block conductors 48a and 48b are not limited thereto.

The interlayer connection conductors 48 are formed of one or more block conductors 48a and 48b.

The block conductors 48a and 48b have a relatively greater volume and surface area than the other interlayer connection conductors 48. That is, the block conductors 48a and 48b may have a width that is greater than a width of a via hole. For example, the width of the block conductors 48a and 48b may be greater than twice or three times a width of a via hole used for forming an interlayer connection conductor 48 within the semiconductor package 100. In this example, the block conductors 48a and 48b are not a via formed by filling a via hole with a conductive material. The block conductors 48a and 48b may have an overall shape of a block having its upper surface substantially parallel to its lower surface.

In FIG. 1, the block conductors 48a and 48b are disposed on positions corresponding to the active surface of the electronic element 1, and are disposed within one of the build-up layers 20. The thicknesses of the block conductors 48a and 48b may be equal to or similar to that of a thickness of the build-up layers 20.

The block conductors 48a and 48b are disposed above the active surface of the electronic element 1, so as to face the active surface of the electronic element 1.

The block conductors 48a and 48b are electrically connected to the terminals 1a and 1 b of the electronic element 1 and the wiring layers 41, 43, and 45, to electrically connect the terminals 1a and 1 b of the electronic element 1 and the wiring layers 41, 43, and 45 to each other. According to the present embodiment, the electronic element 1 includes power terminals 1a and ground terminals 1b. Therefore, the block conductors 48a and 48b may be individually categorized as a first block conductor 48a connected to the power terminal 1a, and a second block conductor 48b connected to the ground terminal 1b. Here, the terms “first” and “second” are used to merely distinguish between the two types of block conductors and do not signify intrinsic orders.

In a case in which a plurality of power terminals is are provided on the electronic element 1, as in the embodiment illustrated in FIG. 2, the plurality of power terminals 1a may all be connected to the first block conductor 48a. Similarly, in a case in which a plurality of ground terminals 1b on the electronic element 1, the plurality of ground terminals 1b may all be connected to the second block conductor 48b.

The block conductors 48a and 48b may be obtained by: forming the insulating layer L2, forming the cavity 26 within the insulating layer L2 as illustrated in FIG. 5C through operations such as exposure, etching, and the like, thereby exposing the wiring layer 45, and then filling the cavity with a conductive material by a method such as plating, or the like. As a result, the block conductors 48a and 48b may have a shape that corresponds to the shape of the cavity 26 formed within the insulating layer L2.

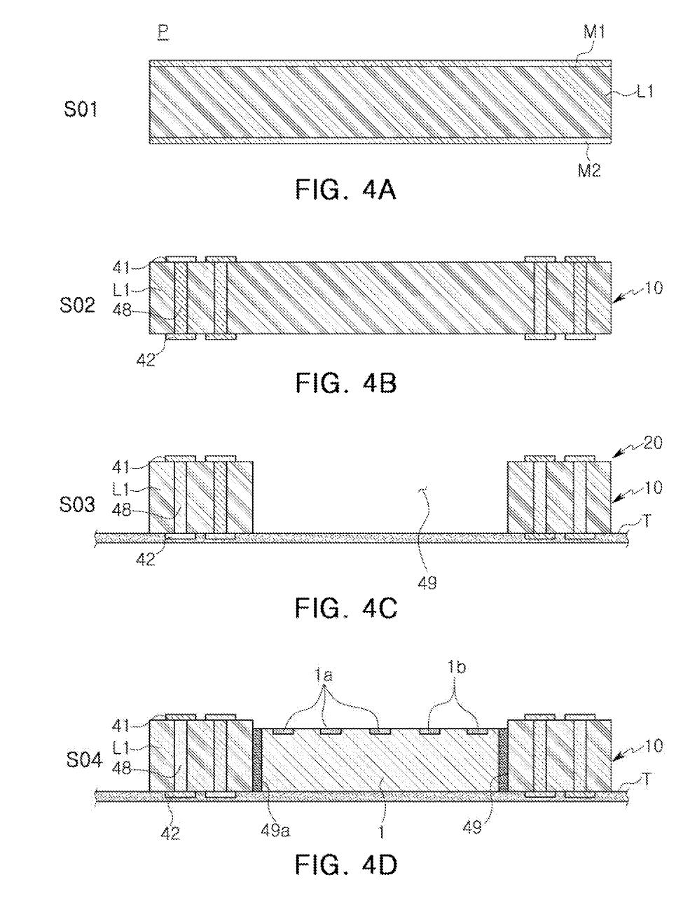

FIGS. 3 through 3E are perspective views of various modified examples of block conductors 48a and 48b according to the present disclosure. Referring to FIGS. 3A through 3E, the block conductors 48a and 48b may be formed in a parallelepiped shape, as illustrated in FIG. 3A. However, the shape of the block conductors 48a and 48b is not limited thereto. For instance, the block conductors 48a and 48b may be formed to correspond to a layout of the terminals 1a and 1b of the electronic element 1, as illustrated in FIGS. 3B through 3E. The block conductors may have a lower surface and an upper surface that are parallel to each other, and the width of the block conductors may be greater than a vertical height of the block conductors.

One or more connection pads 50 may be disposed on a surface of the block conductors 48a and 48b. An external connection terminal 60 may be bonded to the connection pad 50, or an electronic component (not shown) may be mounted on the connection pad 50. By mounting an electronic component on a connection pad 50 disposed on such block conductors 48a and 48b, a length of an electrical path between the electronic component and the electronic element 1 may be significantly reduced. In addition, since the block conductors 48a and 48b are disposed along the electrical path, heat generated in the electrical path may be effectively discharged, such that power loss caused by the heat generation through the electrical path may be significantly reduced.

A board part 40 having the configuration described above may be implemented with various kinds of boards that are well known in the art. For example, the board part 40 may be implemented with a printed circuit board, a ceramic substrate, a glass substrate, a flexible substrate or the like.

The board part 40 may be a multilayer board having the plurality of wiring layers 41 to 45. Although the embodiment of the board part 40 illustrated above includes five wiring layers 41 to 45 as an example, a board part 40 according to another example of the present disclosure may include more wiring layers or fewer wiring layers, as needed.

In the semiconductor package 100 described above, the block conductors 48a and 48b may be connected to the terminals 1a and 1 b of the electronic element 1, which are heating elements. Therefore, the semiconductor package 100 may effectively discharge the heat generated in the electronic element 1.

In the event that the heat generated in the electronic element 1 is not smoothly discharged, the heat may be transferred along the electrical path of the electronic element 1, which results in a temperature increase of the electrical path. In this case, the elevation of temperature increases the resistance of the electrical path, and the resulting increase in resistance results in increased electrical loss.

The electronic element may have main power lines through which a current of a few milliamperes (mA) to tens of amperes (A) may flow. However, in a case of a printed circuit board according to a related art, a via, which is an interlayer connection conductor, may be formed in a circular structure and may impose a size limit. However, a module or a package may require a printed circuit board that is thin and light while maintaining multifunctionality, and the formation of a via in the circular structure imposes limits in designing and manufacturing the board.

In order to eliminate the design limitations placed by forming a via, the semiconductor package 100 according to the present embodiment may utilize block conductors 48a and 48b. Since the semiconductor package optimizes the use of the interlayer connection conductors, which form the electrical path to the electronic component through the block conductors, and a structure of a pattern, an IR drop may be significantly reduced and power loss may be significantly reduced. Further, if the power loss is reduced, an amount of heat generated in the electrical path may be reduced and, consequently, additional loss caused by the heat may also be significantly reduced, whereby efficiency of the electronic element may be increased.

In addition, since the block conductors 48a and 48b are disposed on the electrical path of the electronic element 1, it is not necessary to add a separate heat dissipating member onto the inactive surface of the electronic element 1, in order to discharge the heat of the electronic element 1.

Next, an example of a method of manufacturing a semiconductor package will be described.

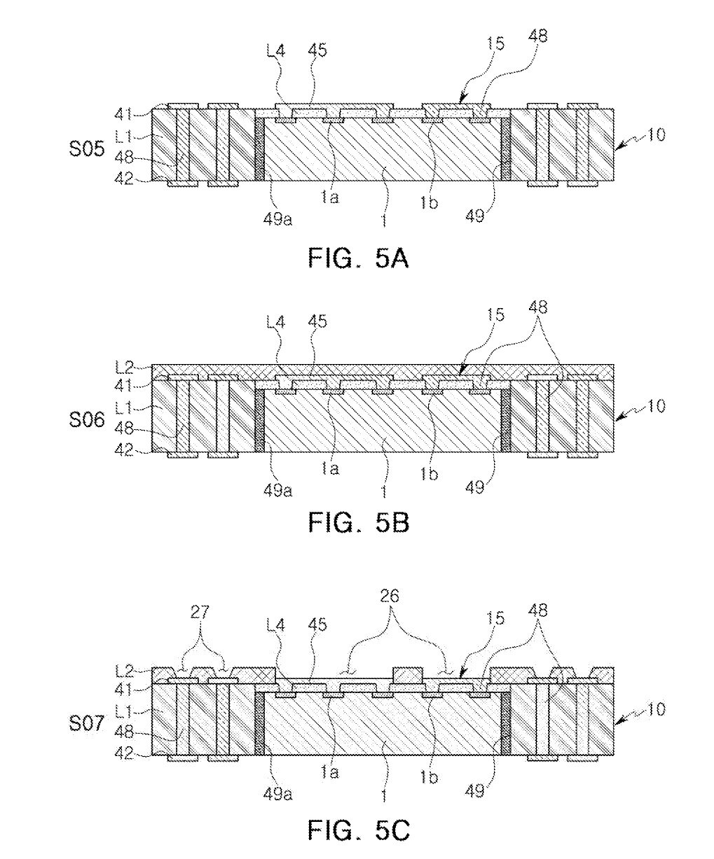

FIGS. 4A through 6C are views illustrating an example of a method of manufacturing a semiconductor package as illustrated in FIG. 1.

First, as illustrated in FIG. 4A, a laminate P is prepared such that the laminate P includes an insulating layer L1 and metal layers M1 and M2, formed on the upper and lower surfaces of the insulating layer L1 (S01). According to one example, a copper clad laminate (CCL) may be used as the laminate P.

Next, the wiring layers 41 and 42 are formed by patterning the metal layers M1 and M2 of the laminate P (S02). The formation of the wiring layers 41 and 42 from the metal layers M1 and M2 may be performed by an exposure and etching operation, or the like.

At the same time, a predetermined region of the metal layers M1 and M2 may be removed in order to subsequently form an element accommodating region 49. That is, in this operation, in order to form the element accommodating region 49 in the insulating layer L1, the region of the metal layers M1 and M2 that corresponding to an opening for the element accommodating region 49 is removed. Therefore, an area of the metal layers M1 and M2 corresponding to the size and shape of the element accommodating region 49 is removed.

In addition, in the present operation, the interlayer connection conductor 48 is formed in the insulating layer L1. The interlayer connection conductor 48 may be formed by forming a through-hole in the insulating layer L1 and then filling a conductive material into the through-hole.

Next, a portion of the insulating layer L1 is removed in order to form the element accommodating region 49, and a tape T is then attached to one surface of the core layer 10 in order to support the electronic element 1 (S03).

The element accommodating region 49 is formed to have a through-hole, and the element accommodating region 49 has a size or shape that corresponds to the size or shape of the embedded electronic element 1.

In this example, the wiring layer is not disposed on a region in which the element accommodating region 49 is to be formed. Therefore, the element accommodating region 49 may be easily formed by removing the insulating layer, using a laser. However, the method of forming the element accommodating region 49 is not limited thereto; various methods, such as a punching method and a drill method, may be used, as long as these methods may form the element accommodating region 49 in the core layer 10.

The electronic element 1, having the terminals 1a formed on the active surface, is disposed within the element accommodating region 49. In this case, the electronic element 1 is disposed so that the inactive surface thereof is in contact with the tape T.

When the electronic element 1 is disposed within the element accommodating region 49, the insulating member 49a is filled into the element accommodating region 49 and then cured. The insulating member 49a may be introduced into the element accommodating region 49 in order to fill a space or gap around the electronic element 1 and to affix the electronic component 1 in place.

The insulating member 49a is formed through a process of introducing a liquid gel into the component accommodating region 49 and curing the liquid gel into a hardened insulating member 49a.

Next, after the tape T is removed, the rewiring layer 15 is formed on the active surface of the electronic element 1 (S05). The rewiring layer 15 may be implemented by forming the insulating layer L4 on the active surface of the electronic element 1 and forming the wiring layer 45 on the insulating layer L4 through a photolithography operation. In this case, the plurality of connection conductors 48 connected to the terminals of the electronic element 1 are formed within the insulating layer L4.

Next, a build-up layer 20 is formed.

First, the insulating layer L2 is laminated on one surface of the core layer (S06). In FIG. 5B, for example, the build-up layer 20 is first formed on one surface of the core layer 10 adjacent to the active surface of the electronic element 1. However, the arrangement of the build-up layer 20 is not limited thereto, and the arrangement of the build-up layer 20 may vary in another example. For example, the build-up layer 20 may be first formed on the other surface of the core layer 10, or may be simultaneously formed on both top and bottom surfaces of the core layer 10.

Next, a via hole 27 and a cavity 26 are formed to form the connection conductor 48 in the insulating layer L2.

The interlayer connection conductor 48 may be formed by photolithography. In the present operation, a plurality of via holes 27 and cavities 26 are formed within the insulating layer L2 through an exposure and etching operation.

In the present operation, the cavity 26 is provided above the electronic element 1, and the wiring layer 45 of the rewiring layer 15 is exposed to the outside through the cavity 26.

Next, the via holes 27 and the cavities 26 are filled with the conductive material through a plating operation, in order to form the interlayer connection conductor 48 and the wiring layer 41 (S08). In the present operation, the conductive material filled in the cavities 26 eventually forms the block conductors 48a and 48b. Therefore, the block conductors 48a and 48b have a thickness equal to or similar to that of the insulating layer L2, and electrically connect both top and bottom surfaces of the insulating layer with each other.

Meanwhile, since the wiring layer 43 formed in the present operation is the wiring layer disposed at the outermost portion among the wiring layers 41 to 45, the wiring layer 43 includes at least one electrode pad 50.

Next, after each insulating protective layer 30 is formed on the corresponding build-up layer 20, a plurality of openings are formed in each of the insulating protective layers 30 to expose the electrode pads 50 to the outside (S09). The insulating protective layers 30 may be formed of solder resist. According to one example, the insulating protective layers 30 may also be formed in a multilayer form, as needed.

The build-up layers 20 are completed by repeatedly performing the above-mentioned operations (S06 to S09) for each surfaces of the core layer 10. As a result, the build-up layers 20, disposed on both top and bottom surfaces of the core layer 10, are completed, and the electronic element 1 is fully embedded within the core layer 10 and the build-up layers 20.

The present embodiment describes an example in which only one layer of the build-up layer 20 is laminated on both top and bottom surfaces of the core layer 10. However, the configuration of the present disclosure is not limited thereto. For example, the build-up layers 20 may also be formed in a multilayer form by laminating a plurality of insulating layers on the core layer 10 and forming one wiring layer between the plurality of insulating layers.

Next, the semiconductor package 100 may be completed by forming an external connection terminal 60 on the electrode pad 50.

In the method of manufacturing the semiconductor package according to the present embodiment, having the configuration as described above, the block conductors may be disposed over the power lines of the electronic element, to effectively discharge heat applied to the power lines.

In a case in which the electronic element is a power amplifier, very high heat may be generated in the power lines. Therefore, since loss caused by the heat in the power lines may be reduced, according to the present disclosure, efficiency of the electronic element may be increased.

In addition, while a laser drilling method or a mechanical drilling method is conventionally used to form the interlayer connection conductor, in this case, it is difficult to form the cavity having a wide size, as described in the present embodiment. However, according to the method of manufacturing the semiconductor package according to the present embodiment, since the cavity is formed through an exposure and etching operation, the block conductors may be formed in various sizes and shapes.

Meanwhile, the semiconductor package according to the present disclosure is not limited to the above-mentioned embodiments, but may be variously modified.

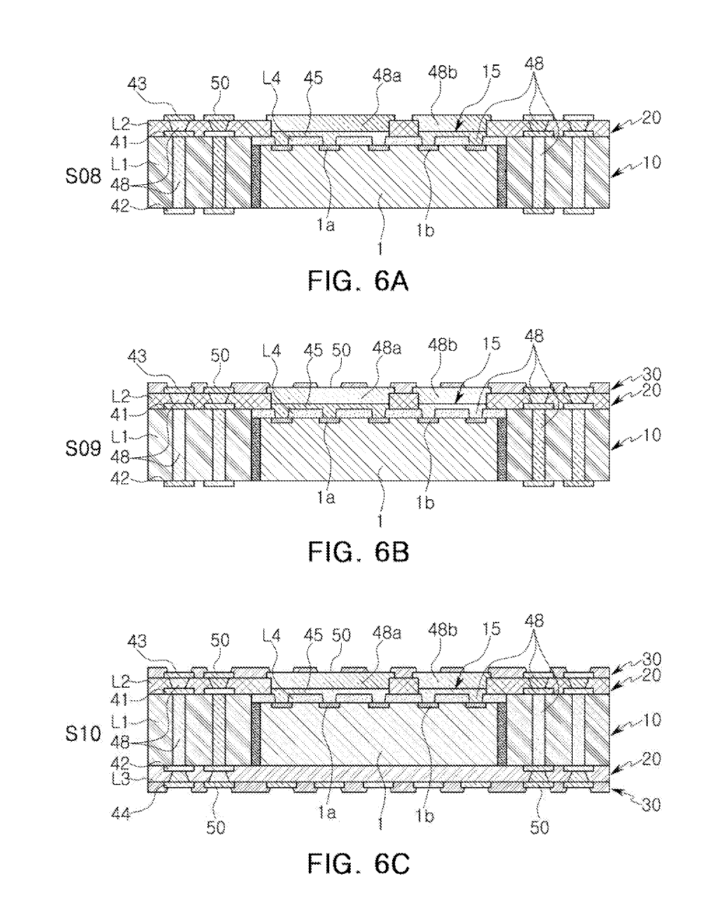

FIG. 7 is a cross-sectional view schematically illustrating another embodiment of a semiconductor package according the present disclosure.

Referring to FIG. 7, a semiconductor package 200 includes an electronic element 1 that includes terminals 1a and 1b, and the terminals 1a and 1b have a shape of a pad. In addition, the block conductors 48a and 48b are connected to the terminals 1a and 1b having the pad shape via a surface contact. For example, the terminals according to the present embodiment may have a size and shape corresponding to an area of lower surfaces of the block conductors 48a and 48b.

In this case, since a contact area between the terminals 1a and 1b of the electronic element 1 and the block conductors 48a and 48b may be significantly increased, thermal conductivity may be increased to significantly increase the heat dissipation effect.

The block conductors 48a and 48b according to the present embodiment may be formed by a plating method, and may be formed by growing the conductive material from the terminals 1a and 1b of the electronic element 1. However, the method of forming the block conductors 48a and 48b is not limited thereto.

Meanwhile, in the semiconductor package 200 according to the present embodiment, the rewiring layer is omitted and the terminals 1a and 1b of the electronic element 1 are directly connected to the block conductors 48a and 48b. However, the configuration of the semiconductor package 200 is not limited thereto. According to another embodiment, the semiconductor package 200 also includes the rewiring layer, based on the size of the electronic element 1.

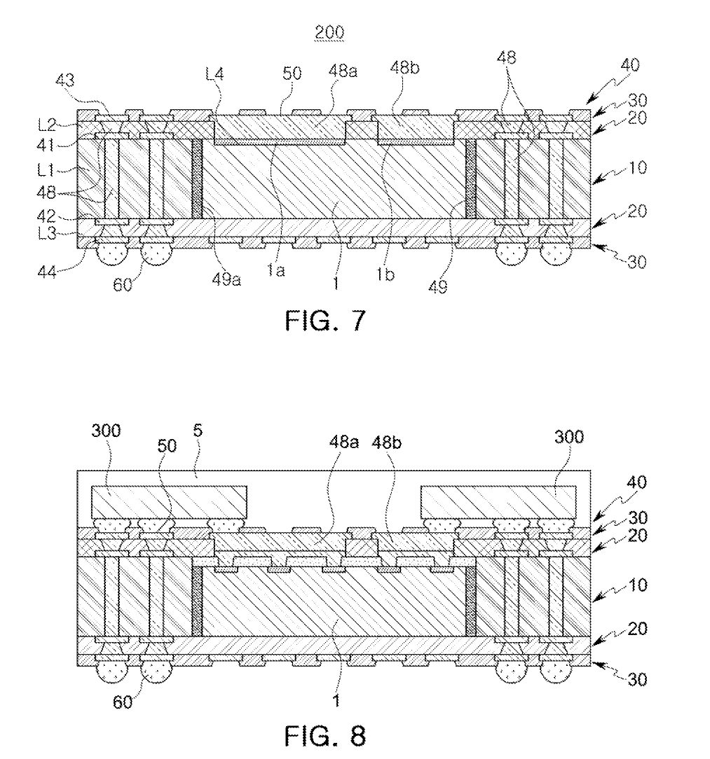

FIG. 8 is a cross-sectional view schematically illustrating an example of an electronic element module according to the present disclosure.

Referring to FIG. 8, an electronic element module according to the present embodiment has at least one electronic component 300 mounted on the semiconductor package 100, illustrated in FIG. 1 described above. In addition, the electronic component 300 sis encapsulated by an encapsulating part 5.

In this embodiment, the connection pads 50 are disposed on both top and bottom surfaces of the semiconductor package 100. Therefore, a second surface of both top and bottom surfaces may be used to mount a main substrate, and a first surface may be used to mount the electronic component 300, which is separately manufactured.

As the electronic component 300, at least one of a known active element or passive element may be used. In addition, as the encapsulating part 5, a known encapsulating member such as epoxy molding compound (EMC) may be used.

In the semiconductor package 100 according to the present embodiment, the connection pads 50 may be disposed on the entirety of a first surface. Accordingly, since a plurality of connection pads 50 may be provided through the first surface, a plurality of electronic components 300 may be mounted on the first surface. As a result, an increased degree of integration may be achieved.

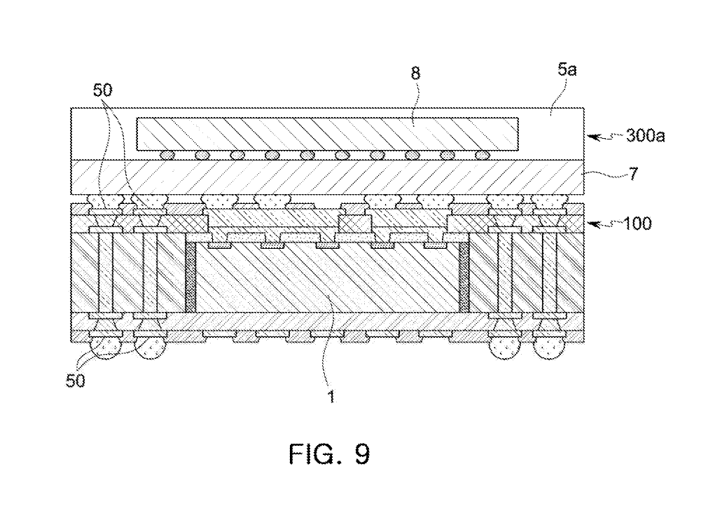

FIG. 9 is a cross-sectional view schematically illustrating another embodiment of an electronic element module according to the present disclosure.

Referring to FIG. 9, an electronic element module according to the present embodiment is configured in a package on package (PoP) form, in which an electronic component 300a of a package form is mounted on the semiconductor package 100, illustrated in FIG. 1, described above.

In this embodiment, the connection pads 50 are disposed on both top and bottom surfaces of the semiconductor package 100. Therefore, a second surface of both top and bottom surfaces may be used to mount a main substrate, and a first surface may be used to mount the electronic component 300a, which is separately manufactured.

As the electronic component 300a, any one of known semiconductor packages may be used. For example, the electronic component 300a may be configured so that an electronic element 8 is mounted on a substrate 7 and is encapsulated by an encapsulating part 5a. However, the electronic component 300a is not limited thereto, and all electronic components may be used as long as they may be mounted on the first surface of the semiconductor package 100.

In the semiconductor package 100 according to the present embodiment, the connection pads 50 may be disposed on the entirety of a first surface. Accordingly, since a plurality of connection pads 50 may be provided through the first surface, a package having a plurality of I/O terminals may also be mounted on the first surface. In addition, bonding reliability with the electronic component 300a mounted on the first surface may be increased.

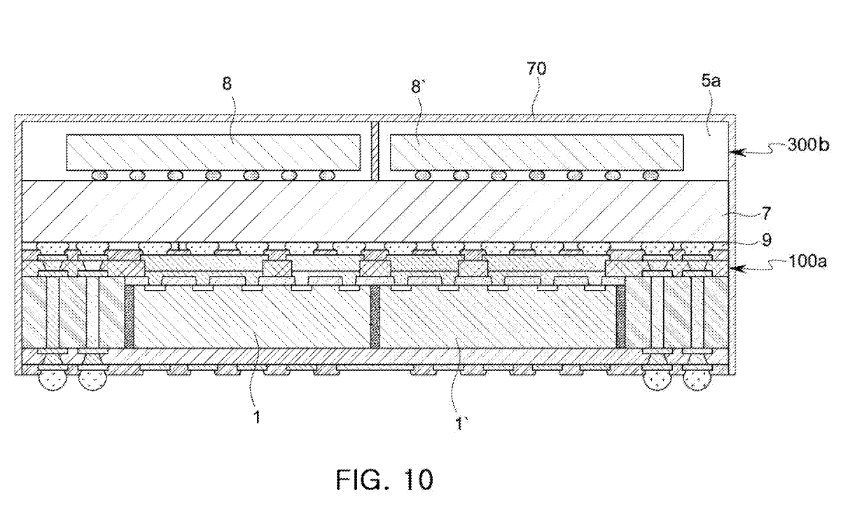

FIG. 10 is a cross-sectional view schematically illustrating another embodiment of an electronic element module according to the present disclosure. Referring to FIG. 10, an electronic element module according to the present embodiment is configured in a package on package (PoP) form, in which an electronic component 300b of a package form is mounted on the semiconductor package 100a, which is a modification of the semiconductor package 100 illustrated in FIG. 1 described above.

The semiconductor package 100a is only different from the semiconductor package illustrated in FIG. 1 in that it includes a plurality of electronic elements 1 and 1′. However, the semiconductor package 100a may be configured to be the same as the semiconductor package illustrated in FIG. 1 in other configurations. The electronic elements 1 and 1′ may include a power amplifier, a filter, and an integrated circuit (IC), and may be embedded in a form of bare die, as described above.

As the electronic component 300b, any one of known semiconductor packages may be used. According to this embodiment, the electronic component 300a is configured so that electronic elements 8 and 8′ are mounted on a substrate 7 and are encapsulated by an encapsulating part 5a; however, the configuration of the electronic component 300a is not limited thereto.

In addition, according to the present embodiment, a metal layer 70 is disposed on a surface of the electronic element module.

The metal layer 70 may be provided to block electromagnetic waves. Therefore, the metal layer 70 may be formed along an interface between the semiconductor package 100a and the electronic component 300b. In this case, an insulating material 9 may be filled between the semiconductor package 100a and the electronic component 300b.

Meanwhile, the metal layer 70 according to the present embodiment is not limited to the above-mentioned configuration, and may also be formed only on a surface of either the semiconductor package 100a or the electronic component 300b, as needed. In addition, as illustrated in FIG. 10, the metal layer 70 may be interposed between the electronic elements 8 and 8′ included in the electronic component 300b, to block interference between the electronic elements 8 and 8′.

The semiconductor package according to the present embodiment having the configuration described above may embed the electronic elements 1 and 1′ in a form of the bare die therein and may have the connection pads 50 disposed on both top and bottom surfaces thereof. Therefore, a size of the semiconductor package may be significantly reduced, so that the semiconductor package may be utilized in a PoP structure.

Further, since the heat generated in the electronic element may be effectively discharged through the block conductors, an increase in a temperature of the semiconductor package during an operation may be suppressed.

In addition, the electronic element module according to the present embodiment may be manufactured by mounting a variety of forms of electronic components in the semiconductor package. As a result, a degree of integration may be increased.

As set forth above, according to the embodiments in the present disclosure, since the semiconductor package optimizes the interlayer connection conductors, which form the electrical path connected to the electronic element through the block conductors, and the structure of the pattern, the IR drop may be significantly reduced and the power loss may be significantly reduced. Further, if the power loss is reduced, the amount of heat generated in the electrical path may be reduced and, consequently, additional loss caused by the heat may also be significantly reduced, whereby efficiency of the electronic element may be increased.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A semiconductor package comprising:
a board part comprising a core layer having an element accommodating region disposed therein, and build-up layers disposed on top and bottom surfaces of the core layer;
an electronic element disposed in the element accommodating region; and
block conductors disposed on the build-up layers and electrically connected to terminals of the electronic element.

2. The semiconductor package of claim 1, wherein the block conductors are directly formed on the terminals of the electronic element through a plating method.

3. The semiconductor package of claim 1, wherein rewiring layers are disposed on the terminals of the electronic element, and
the block conductors are disposed on wiring layers that are disposed on the rewiring layers.

4. The semiconductor package of claim 3, wherein the rewiring layers are disposed within the element accommodating region.

5. The semiconductor package of claim 1, further comprising insulating protective layers disposed on the build-up layers,
wherein the insulating layers include one or more openings that partially expose the block conductors.

6. The semiconductor package of claim 1, wherein the electronic element is a power amplifier, and
the terminals comprise a plurality of power terminals and a plurality of ground terminals.

7. The semiconductor package of claim 6, wherein the block conductors comprise a first block conductor connected to the plurality of power terminals, and a second block conductor connected to the plurality of ground terminals.

8. The semiconductor package of claim 1, wherein the block conductors and the build-up layers have substantially the same thickness.

9. The semiconductor package of claim 1, wherein the block conductors are disposed on an active surface of the electronic element.

10. The semiconductor package of claim 1, wherein the terminals of the electronic element are formed as pads having a size corresponding to an area of the block conductors, and
the block conductors are formed by growing a conductive material from the terminals, by a plating method.

11. An electronic element module comprising:
a semiconductor package comprising an electronic element disposed within a core layer, a build-up layer laminated on the core layer, and one or more block conductor disposed within the build-up layer to discharge heat of the electronic element; and
at least one electronic component mounted on the semiconductor package.

12. The electronic element module of claim 11, further comprising a metal layer disposed along an interface between the semiconductor package and the electronic component to block electromagnetic wave.

13. A semiconductor package comprising:
an electronic element disposed within a core layer, terminals of the electronic element being exposed through an opening of the core layer;
a build-up layer covering the opening of the core layer; and
a block conductor disposed within the build-up layer and is electrically connected to the terminals.

14. The semiconductor package of claim 13, wherein the build-up layer contacts the electronic element.

15. The semiconductor package of claim 13, wherein one or more block conductors is disposed within the build-up layer, and the one or more block conductors and the build-up layer substantially seal the opening through which the terminals of the electronic element are exposed from the core layer.
